(19) United States
(12) Patent Application Publication
(10) Pub. No.: US 2016/0109948 A1
(43) Pub. Date: Apr. 21, 2016

(54) TOUCHSCREEN PANEL AND ELECTRONIC DEVICE INCLUDING THE SAME

(71) Applicant: SAMSUNG ELECTRO-MECHANICS CO., LTD., Suwon-si (KR)

(72) Inventors: In Wha JEONG, Suwon-si (KR); Jong Heum PARK, Suwon-si (KR); Hak Ryong KIM, Suwon-si (KR)

(73) Assignee: SAMSUNG ELECTRO-MECHANICS CO., LTD., Suwon-si (KR)

(21) Appl. No.: 14/627,009

(22) Filed: Feb. 20, 2015

(30) Foreign Application Priority Data
Oct. 17, 2014 (KR) 10-2014-0140663

(51) Int. Cl. G06F 3/01; H01L 41/113; H01L 41/09; G06F 3/041; G06F 1/32

(52) U.S. Cl. CPC G06F 3/016; G06F 3/041; G06F 3/0416; G06F 1/3262; G06F 1/3265; H01L 41/09; H01L 41/113

(57) ABSTRACT

A touchscreen panel includes: a panel; a piezoelectric vibrating part provided on a side of the panel to generate power and vibrations; a touch sensing part provided on one surface of the piezoelectric vibrating part opposite to the other surface of the piezoelectric vibrating part facing the panel; and a substrate provided on a side of the touch sensing part.

### CROSS-REFERENCE TO RELATED APPLICATION

This application claims the priority and benefit of Korean Patent Application No. 10-2014-0140663 filed on Oct. 17, 2014, with the Korean Intellectual Property Office, the disclosure of which is incorporated herein by reference.

### BACKGROUND

The present inventive concept relates to a touchscreen panel and an electronic device including the same.

In accordance with the trend for the use of computers to be gradually expanded, there have been limitations in efficiently interfacing with computers using only a keyboard and a mouse, devices commonly serving as user interface devices.

Therefore, as a relatively simple user interface device having a low malfunction rate, able to be intuitively used by a majority of users, touchscreen panels have been developed.

However, since touchscreen panels commonly utilize a scheme in which a user interfaces with a computer by touching a touchscreen panel with a finger, or the like, without using separate buttons, it is difficult to provide a feedback to the user while interaction with such a touchscreen.

Therefore, in order to provide the feedback in the case in which a user interfaces with a computer using the touchscreen panel, a haptic function using vibrations generated by a piezoelectric actuator has been added to electronic devices.

However, such piezoelectric actuators have been somewhat problematic, in that a large amount of battery power of the electronic device may be consumed thereby.

### SUMMARY

An aspect of the present inventive concept may provide a touchscreen panel capable of generating power and vibrations, and an electronic device including the same.

According to an aspect of the present inventive concept, a touchscreen panel may include: a panel; a piezoelectric vibrating part provided on a side of the panel to generate power and vibrations; a touch sensing part provided on one surface of the piezoelectric vibrating part opposite to the other surface of the piezoelectric vibrating part facing the panel; and a substrate provided on a side of the touch sensing part.

The piezoelectric vibrating part may include a piezoelectric harvesting part generating power from vibrations of the panel and a piezoelectric actuator part generating vibrations using the power generated by the piezoelectric harvesting part.

Therefore, the piezoelectric actuator part may generate the vibrations using the power generated by the piezoelectric harvesting part, without using power separately supplied by a battery.

According to another aspect of the present inventive concept, an electronic device may include: the touchscreen panel as described above; and a case accommodating the touchscreen panel therein.

### BRIEF DESCRIPTION OF DRAWINGS

The above and other aspects, features and other advantages of the present inventive concept will be more clearly understood from the following detailed description taken in conjunction with the accompanying drawings, in which:

FIG. 1 is a perspective view of an electronic device according to an exemplary embodiment of the present inventive concept;

FIG. 2 is a schematic cross-sectional view taken along line A-A′ of FIG. 1;

FIG. 3 is a partial plan view of a piezoelectric vibrating unit according to an exemplary embodiment of the present inventive concept;

FIG. 4 is a partial plan view illustrating a modified example of a piezoelectric vibrating unit according to an exemplary embodiment of the present inventive concept;

FIG. 5 is a partial plan view illustrating another modified example of a piezoelectric vibrating unit according to an exemplary embodiment of the present inventive concept; and

FIG. 6 is a schematic cross-sectional view of an electronic device according to another exemplary embodiment of the present inventive concept.

### DETAILED DESCRIPTION

Exemplary embodiments of the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements maybe exaggerated for clarity, and the same reference numerals will be used throughout to designate the same or like elements.

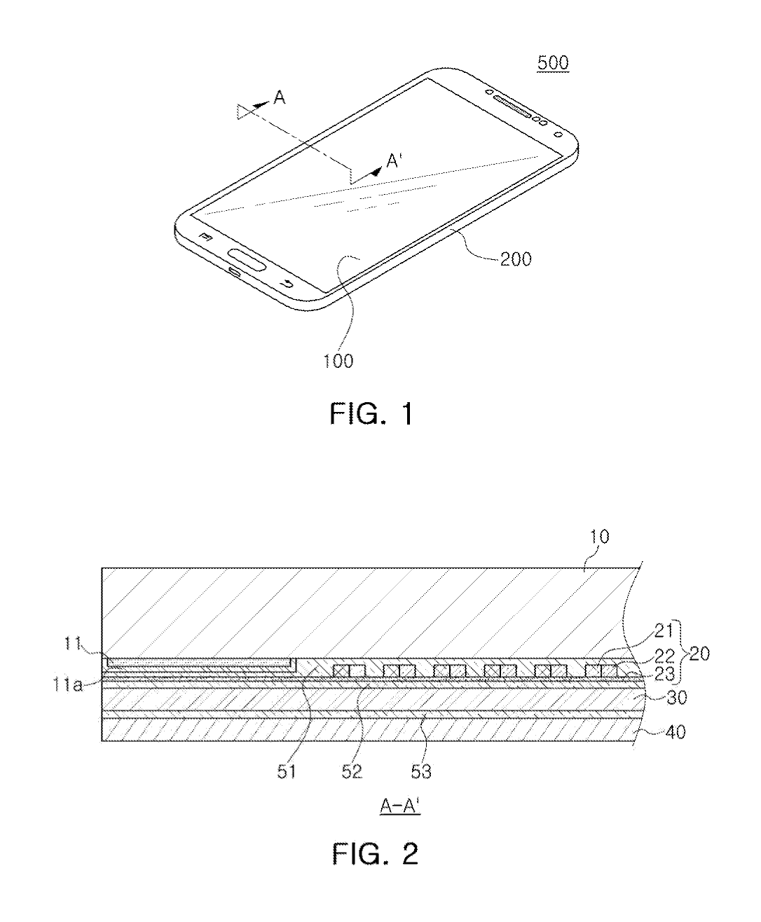

FIG. 1 is a perspective view of an electronic device according to an exemplary embodiment of the present inventive concept; and FIG. 2 is a schematic cross-sectional view taken along line A-A′ of FIG. 1.

Referring to FIGS. 1 and 2, an electronic device 500 according to an exemplary embodiment of the present inventive concept may include a touchscreen panel 100 and a case 200 on which the touchscreen panel 100 is mounted.

The case 200 may be a member forming an overall exterior of the electronic device 500 in which the touchscreen panel 100 and various other electronic elements which are necessary to drive the electronic device 500 are installed.

That is, the case 200 may serve to protect the touchscreen panel 100 and the electronic elements.

A used herein, the electronic device 500 according to the present exemplary embodiment refers to various electronic devices such as cellular phones, personal digital assistants (PDAs), navigation units, laptops, and the like, which require a haptic function.

The touchscreen panel 100 may include a panel 10, a piezoelectric vibrating part 20, a touch sensing part 30, and a substrate 40.

The panel 10 may be provided in an uppermost side of the touchscreen panel 100, to receive a touch input from a touching object such as a finger of a user, a touch pen, or the like.

In addition, the panel 10 may have transparency so that the user may recognize an image provided from a display.

That is, the panel 10 may be formed of glass or tempered glass, but the type of the panel 10 is not necessarily limited thereto. For example, the panel 10 may also be formed using a material having transparency such as a transparent plastic.

In addition, a bezel part 11 may be formed around an edge of a bottom surface of the panel 10, wherein the bezel part 11 is provided to cover an electrode wiring of the touch sensing part 30.

Meanwhile, the piezoelectric vibrating part 20 may be provided on a side of the panel 10. That is, the piezoelectric vibrating part 20 may be provided below the panel 10 to generate power by pressure applied from the panel 10 and provide the haptic function.

More particularly, the piezoelectric vibrating part 20 may include a piezoelectric harvesting part 21 generating power from vibratory pressure applied from the panel 10, a piezoelectric actuator part 22 generating vibrations using the power generated by the piezoelectric harvesting part 21, and a piezoelectric vibrating part substrate 23 on which the piezoelectric harvesting part 21 and the piezoelectric actuator part 22 are disposed.

The piezoelectric harvesting part 21, provided to generate power, may generate power using pressure applied by deformation in the panel 10 occurring in the case in which the user applies pressure to the panel 10 with the finger, the touch pen, or the like.

That is, the piezoelectric harvesting part 21 may be deformed by the deformation of the panel 10 and may be not only basically formed of a ceramic piezoelectric material having a large amount of power generation but also a polymer having excellent physical flexibility or a hybrid piezoelectric material in which a polymer and ceramic are mixed.

Here, the type of piezoelectric material may include polyvinylidene fluoride (PVDF), barium titanate (BaTiO₃), and lead zirconate titanate (PZT). In addition, the type of piezoelectric material may also include lead-free piezoelectric materials such as NKN based, BZT-BCT based, BNT based, BSNN, BNBN based, and the like, PLZT, P(VDF-TrFE), crystal, tourmaline, Rochelle salt, BaTiO₃, ammonium dihydrogen phosphate (ADP), tartaric acid, ethylenediamine (EDA), and the like.

However, the type and quality of the piezoelectric material are not limited to the exemplary embodiment provided herein by way of example, and other types and qualities of piezoelectric material may also be used as long as they generate a sufficient amount of power through an external power source.

In addition, the piezoelectric harvesting part 21 may be mounted on the piezoelectric vibrating part substrate 23, wherein the piezoelectric harvesting part 21 may be disposed adjacently to the piezoelectric actuator part 22.

The disposition configuration of the piezoelectric harvesting part 21 and the piezoelectric actuator part 22 will be described in greater detail below.

Meanwhile, the piezoelectric harvesting part 21 may be electrically connected to a separate energy storage unit (not illustrated).

The energy storage unit may be provided as a storing medium for storing the power generated by the piezoelectric harvesting part 21, wherein the above-mentioned energy storage unit may be provided, for example, as a super capacitor, a lithium ion secondary cell, a solid thin film cell, or the like.

That is, the power generated by the piezoelectric harvesting part 21 may be stored in the energy storage unit, and may be supplied to the piezoelectric actuator part 22 in the case in which the piezoelectric actuator part 22 needs to be driven.

In addition, the piezoelectric harvesting part 21 and the piezoelectric actuator part 22 may be provided in pairs. That is, the piezoelectric vibrating part 20 may include a single piezoelectric harvesting part 21 and a single piezoelectric actuator part 22 adjacent to the single piezoelectric harvesting part 21 which are provided in a pair, wherein the pair of the piezoelectric harvesting part 21 and the piezoelectric actuator part 22 includes a plurality of pairs of the piezoelectric harvesting part 21 and the piezoelectric actuator part 22 that may be provided on the piezoelectric vibrating part substrate 23 to be spaced apart from each other.

However, the piezoelectric harvesting part 21 and the piezoelectric actuator part 22 may also be mounted on the piezoelectric vibrating part substrate 23 by dividing the piezoelectric vibrating part substrate 23 into portions in which the piezoelectric harvesting part 21 and the piezoelectric actuator part 22 are respectively disposed.

That is, a shape in which the piezoelectric harvesting part 21 and the piezoelectric actuator part 22 are mounted on the piezoelectric vibrating part substrate 23 is not limited.

The piezoelectric actuator part 22, provided to operate the haptic function, may vibrate the electronic device 500 in the case in which power is applied thereto, and may be formed of a polymer material or a PZT material.

To this end, the piezoelectric actuator part 22 may be electrically connected to the energy storage unit, to receive the power from the energy storage unit.

That is, the piezoelectric actuator part 22 according to the exemplary embodiment of the present inventive concept may be operated using the power generated by the piezoelectric harvesting part 21.

Here, since power is required to drive the piezoelectric actuator part 22, the piezoelectric actuator part 22 has been generally driven using power in a battery included in the electronic device, according to a related art.

As a result, the battery is relatively rapidly discharged due to power used to drive the piezoelectric actuator part 22 and needs to be charged relatively frequently.

However, the piezoelectric vibrating part 20 according to the exemplary embodiment of the present inventive concept may include the piezoelectric harvesting part 21 separately provided to drive the piezoelectric actuator part 22.

Therefore, since the piezoelectric actuator part 22 is operated using power generated by the piezoelectric harvesting part 21, the piezoelectric actuator part 22 may not require power additionally supplied from a battery for driving the piezoelectric vibrating part 20 and may be supplied with self-generated power.

Hereinafter, a process in which the haptic function is operated in the touchscreen panel 100 according to the exemplary embodiment of the present inventive concept will be described in brief. In a case in which a user touches the panel 10, the panel 10 may be deformed.

As such, in the case in which the panel 10 is deformed, the panel 10 may cause deformation in the piezoelectric harvesting part 21 provided below the panel 10.

Therefore, the piezoelectric harvesting part 21 may receive pressure applied from the panel 10, to generate power.

In addition, the generated power may be stored in a separate energy storage unit connected to the piezoelectric harvesting part 21, and the energy storage unit may supply the power to the piezoelectric actuator part 22 at the time of operating the haptic function.

Meanwhile, as described above, the pair of piezoelectric actuator part 22 and the piezoelectric harvesting part 21 may be mounted on the piezoelectric vibrating part substrate 23, and the plurality of pairs of the piezoelectric actuator part 22 and the piezoelectric harvesting part 21 may be mounted on the piezoelectric vibrating part substrate 23.

Hereinafter, various shapes in which the piezoelectric harvesting part 21 and the piezoelectric actuator part 22 are mounted on the piezoelectric vibrating part substrate 23 will be described.

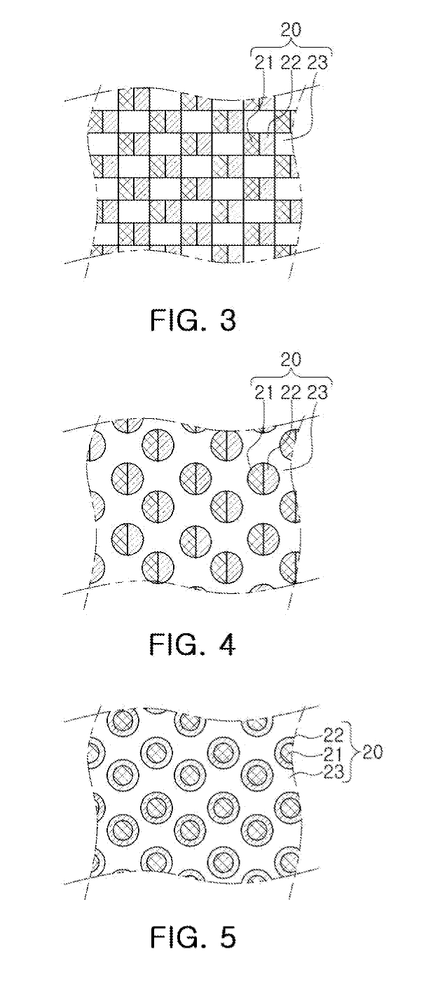

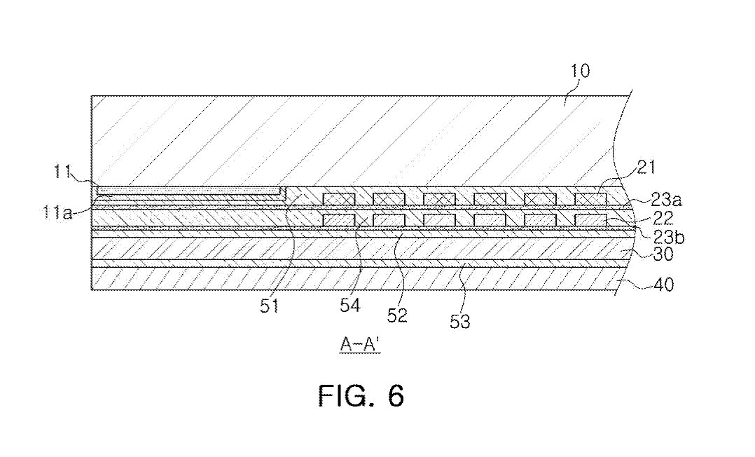

FIG. 3 is a partial plan view of a piezoelectric vibrating unit according to an exemplary embodiment of the present inventive concept; FIG. 4 is a partial plan view illustrating a modified example of a piezoelectric vibrating unit according to an exemplary embodiment of the present inventive concept; FIG. 5 is a partial plan view illustrating another modified example of a piezoelectric vibrating unit according to an exemplary embodiment of the present inventive concept; and FIG. 6 is a schematic cross-sectional view of an electronic device according to another exemplary embodiment of the present inventive concept.

Referring to FIG. 3, the piezoelectric harvesting part 21 and the piezoelectric actuator part 22 may each be provided in a quadrangular shape, and a side of the piezoelectric harvesting part 21 and a side of the piezoelectric actuator part 22 are disposed to be adjacent to each other, such that a pair of the piezoelectric harvesting part 21 and the piezoelectric actuator part 22 may be mounted on the piezoelectric vibrating part substrate 23 to have an overall quadrangular shape when combined.

In addition, referring to FIG. 4, the piezoelectric harvesting part 21 and the piezoelectric actuator part 22 may each be provided in a semicircular shape, and straight line portions of the piezoelectric harvesting part 21 and the piezoelectric actuator part 22 corresponding to diameters of the semicircular shapes, respectively, are disposed to be adjacent to each other, such that a pair of the piezoelectric harvesting part 21 and the piezoelectric actuator part 22 may be mounted on the piezoelectric vibrating part substrate 23 to have an overall circular shape when combined.

In addition, referring to FIG. 5, the piezoelectric actuator part 22 may be provided to surround the piezoelectric harvesting part 21 around an edge of the piezoelectric harvesting part 21.

In addition, referring to FIG. 6, the piezoelectric harvesting part 21 may be provided upwardly of the piezoelectric actuator part 22.

In this case, the piezoelectric harvesting part 21 and the piezoelectric actuator part 22 may be provided to be mounted on different substrates, respectively.

That is, the piezoelectric vibrating part substrate 23 may include a first piezoelectric vibrating part substrate 23a on which the piezoelectric harvesting part 21 is mounted, and a second piezoelectric vibrating part substrate 23b on which the piezoelectric actuator part 22 is mounted.

In addition, the first piezoelectric vibrating part substrate 23a and the second piezoelectric vibrating part substrate 23b may be coupled to each other by a fourth bonding layer 54.

Referring to FIGS. 1 and 2, the first bonding layer 51 may be interposed between the panel 10 and the piezoelectric vibrating part 20. That is, the piezoelectric vibrating part 20 may be coupled to a lower portion of the panel 10 by an adhesive.

Meanwhile, the touch sensing part 30 in which an electrode pattern (not illustrated) and an electrode wiring (not illustrated) are formed may be provided on a lower portion of the piezoelectric vibrating part 20, wherein the electrode wiring is provided around an edge of the touch sensing part 30 facing an edge of the panel 10.

Therefore, the electrode wiring may be visually obscured by the bezel part 11 provided on the bottom surface of the panel 10.

The touch sensing part 30 may provide a region in which the electrode pattern and the electrode wiring are formed, and may be provided on the lower portion of the piezoelectric vibrating part 20 by a second bonding layer 52.

That is, the second bonding layer 52 may be interposed between the piezoelectric vibrating part 20 and the touch sensing part 30 to bond the piezoelectric vibrating part 20 and the touch sensing part 30 to each other.

The electrode pattern formed in the touch sensing part 30 may generate a signal in a case in which a user touches the electrode pattern with a finger, or the like, to allow a controller to recognize touch coordinates.

Here, the electrode pattern provided in the touch sensing part 30 may be formed of a conductive polymer such as an indium-tin oxide (ITO), an indium zinc oxide (IZO), a zinc oxide (ZnO), a carbon nano tube (CNT), a graphene, or poly(3,4-ethylenedioxythiophene) polystyrene sulfonate (PEDOT/PSS), and may be formed in a mesh pattern using copper (Cu), aluminum (Al), gold (Au), silver (Ag), titanium (Ti), palladium (Pd), chromium (Cr), or a combination thereof.

In addition, the electrode pattern may be formed by a plating process or a deposition process such as a sputtering process. In addition, in a case in which the electrode pattern is formed of copper (Cu), a surface of the electrode pattern may be black-oxide treated.

By performing the black-oxide treatment of the electrode pattern as described above, reflection of light may be prevented.

Meanwhile, the electrode patterns may be formed in various patterns known in the art to which the present inventive concept pertains, such as a planar rod shaped pattern, a diamond pattern, a quadrangular pattern, a triangular pattern, a circular pattern, and the like.

The electrode wiring may be connected to the electrode pattern, to serve to transmit or receive an electrical signal to or from the electrode pattern.

In addition, the electrode wiring may be connected to the electrode pattern around an edge of the touch sensing part 30, and the above-mentioned electrode wiring may be typically formed of an opaque metal material. Therefore, the bezel part 11 visually obscuring the electrode wiring may be provided around the edge of the bottom surface of the panel 10 facing the electrode wiring.

Here, the bezel part 11 may be typically formed to have a thickness of 5 to 10 micrometers (μm) , and a color thereof may be black, white, gold, red, green, yellow, gray, violet, brown, blue, or a combination thereof.

In addition, an encapsulating layer 11a may be provided on an outer surface of the bezel part 11 to encapsulate the bezel part 11. In detail, the encapsulating layer 11a may be provided on a surface of the bezel part 11 other than a surface of the bezel part 11 on which the bezel part 11 is in contact with the panel 10.

The encapsulating layer 11a may be formed of an ultraviolet (UV) curing resin, a thermosetting resin, or loctite, and may be applied onto the bezel part 11 by various schemes such as a screen printing scheme, a slit coating scheme, a spray coating scheme, a dispensing scheme, and the like.

The substrate 40 may be provided below the touch sensing part 30. That is, the substrate 40 may be provided on one surface of the touch sensing part 30 which does not face the piezoelectric vibrating part 20.

Here, a third bonding layer 53 bonding the substrate 40 and the touch sensing part 30 to each other maybe interposed between the substrate 40 and the touch sensing part 30.

In addition, the substrate 40 may be an anti-reflection (AR) film or a low-reflection (LR) film. In this case, the AR film may serve to prevent reflection of light and the LR film may serve to reduce reflection of light.

However, the substrate 40 may not necessarily need to be the AR film or the LR film, but may be a display providing an image.

As set forth above, according to exemplary embodiments of the present inventive concept, the touchscreen panel and the electronic device including the same may generate power and vibrations.

While exemplary embodiments have been shown and described above, it will be apparent to those skilled in the art that modifications and variations could be made without departing from the scope of the invention as defined by the appended claims.

What is claimed is:

1. A touchscreen panel comprising:
a panel;
a piezoelectric vibrating part provided on a side of the panel to generate power and vibrations;
a touch sensing part provided on one surface of the piezoelectric vibrating part opposite to the other surface of the piezoelectric vibrating part facing the panel; and
a substrate provided on a side of the touch sensing part.

2. The touchscreen panel of claim 1, wherein the piezoelectric vibrating part includes a piezoelectric harvesting part generating power from vibratory pressure of the panel and a piezoelectric actuator part generating vibrations using the power generated by the piezoelectric harvesting part.

3. The touchscreen panel of claim 2, wherein the piezoelectric harvesting part and the piezoelectric actuator part have quadrangular shapes, respectively.

4. The touchscreen panel of claim 2, wherein the piezoelectric harvesting part and the piezoelectric actuator part have semicircular shapes, respectively, and a side of the piezoelectric harvesting part and a side of the piezoelectric actuator part are in contact with each other to form an overall circular shape when combined.

5. The touchscreen panel of claim 2, wherein the piezoelectric actuator part is provided to surround the piezoelectric harvesting part around an edge of the piezoelectric harvesting part.

6. The touchscreen panel of claim 2, wherein the piezoelectric harvesting part is provided on an upper side of the piezoelectric actuator part.

7. The touchscreen panel of claim 2, wherein the piezoelectric harvesting part is electrically connected to an energy storage unit.

8. The touchscreen panel of claim 7, wherein the piezoelectric actuator part generates vibrations using power stored in the energy storage unit.

9. The touchscreen panel of claim 7, wherein the energy storage unit is provided as any one of a super capacitor, a lithium ion secondary cell, and a solid thin film cell.

10. The touchscreen panel of claim 1, wherein the panel and the piezoelectric vibrating part have a bonding layer interposed therebetween.

11. The touchscreen panel of claim 1, wherein the piezoelectric vibrating part includes a plurality of piezoelectric vibrating parts.

12. The touchscreen panel of claim 1, wherein the panel has a bezel part provided around an edge of a bottom surface of the panel.

13. An electronic device comprising:
the touchscreen panel of claim 1; and
a case accommodating the touchscreen panel therein.
